(19) United States
(12) Patent Application Publication
(10) Pub. No.: US 2006/0279440 A1
(43) Pub. Date: Dec. 14, 2006

(54) Frequency detector in phase locked loop circuit and frequency error detecting method

(75) Inventors: Hui Zhao, Suwon-si (KR); Hyun-soo Park, Seoul (KR); Jae-wook Lee, Osan-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/406,374

(22) Filed: Apr. 19, 2006

(30) Foreign Application Priority Data
Jun. 10, 2005 (KR) 2005-49696

(51) Int. Cl. H03M 7/40

(52) U.S. Cl. 341/67

(57) ABSTRACT

A frequency detector implementing a method capable of detecting a frequency error in a phase locked loop (PLL) circuit at high speed includes a run-length signal detecting unit detecting a run-length signal from a sampled radio-frequency (RF) signal in a frequency detection period, based on a predetermined distribution density of the run-length signal; a counter unit including at least one counter which counts the detected run-length signals in the frequency detection period; an edge counter controlling the frequency detection period by counting passing edges of the sampled radio-frequency signal; and a frequency error generating unit generating a frequency error in the frequency detection period, using the counting result output from the at least one counter and a predetermined reference value.

### CROSS-REFERENCE TO RELATED APPLICATION

This application claims the priority of Korean Patent Application No. 2005-49696, filed on Jun. 10, 2005 in the Korean Intellectual Property Office, the disclosure of which is incorporated herein in its entirety by reference.

### BACKGROUND OF THE INVENTION

1. Field of the Invention

Aspects of the present invention relate to a frequency detector in a phase locked loop (hereinafter referred to as “PLL”) circuit, and a frequency error detecting method, and more particularly, to a frequency detector and method for detecting a frequency error in an optical disc reproducing system at high speed.

2. Description of the Related Art

An optical disc reproducing system reproduces data from an optical disc, such as a compact disc (CD), a digital versatile disc (DVD), a Blue-Ray disc (BD), or a high-definition (HD)-DVD. The optical disc reproducing system requires a sampling clock (or a bit clock), which is synchronized with a radio-frequency (RF) signal, to reproduce the RF signal from an optical disc. In the optical disc reproducing system, the sampling clock is generated by a PLL circuit.

The PLL circuit generates a frequency error to control an oscillating frequency of a controlled oscillator of the PLL circuit. The frequency error is the difference between the frequency of a current sampling clock output from the PLL circuit and a target frequency, and is generated by a frequency detector in the PLL circuit.

FIG. 1 illustrates a conventional frequency detector installed in the PLL circuit. Referring to FIG. 1, the conventional frequency detector includes a maximum run-length detector 101, an edge counter 102, a buffer 103, first and second comparators 104_1 and 104_2, an adder 105, and a multiplexer 106. When receiving a sampled RF signal, the maximum run-length detector 101 detects a maximum run-length mark. The sampled RF signal is received from an analog-to-digital converter (ADC) (not shown) installed in the PLL circuit.

As illustrated in FIG. 2, the sampled RF signal has a series of blocks, each having a fixed length. FIG. 2 is a diagram of the series of blocks. Referring to FIG. 2, a head of each block is constructed using a synchronization pattern. The synchronization pattern includes at least one maximum run-length mark. The maximum run-length detector 101 of FIG. 1 detects a maximum run-length mark from the synchronization pattern. The edge counter 102 counts passing edges (rising edges and falling edges) of the sampled RF signal to control a frequency detection period. Thus, a predetermined value is set in the edge counter 102 such that the frequency detection period has at least a synchronization pattern.

When the counting result reaches the predetermined value, the edge counter 102 provides a positive pulse to the maximum run-length detector 101, the buffer 103, and the multiplexer 106. Then, the maximum run-length detector 101 is cleared to start detecting a maximum run-length in a subsequent frequency detection period. The buffer 103 loads the maximum run-length from the maximum run-length detector 101 and the positive pulse from the edge counter 102.

The first and second comparators 104_1 and 104_2 compare the maximum run-length loaded into the buffer 103 with a predetermined run-length. The first comparator 104_1 outputs “−1” when the maximum run-length loaded into the buffer 103 is greater than the predetermined run-length, and outputs “0” otherwise. The second comparator 104_2 outputs “+1” when the loaded maximum run-length is less than the predetermined run-length, and outputs “0” otherwise. The predetermined run-length is a maximum run-length.

The maximum run-length loaded into the buffer 103 is greater than the predetermined run-length when a sampling clock frequency of the sampled RF signal is greater than a target frequency. In this case, the adder 105 outputs “−1”. The maximum run-length loaded into the buffer 103 is less than the predetermined run-length when the sampling clock frequency of the sampled RF signal is less than the target frequency. In this case, the adder 105 outputs “+1”. If the maximum run-length loaded into the buffer 103 is equal to the predetermined run-length, the adder 105 outputs “0”. Whenever receiving a positive pulse from the edge counter 102, the multiplexer 106 outputs an output of the adder 105 as a frequency error.

As described above, the frequency detector illustrated in FIG. 1 detects a maximum run-length mark from a synchronization pattern and generates a frequency error. However, a maximum run-length is not detected often. For instance, one or two maximum run-length marks may be detected from each block illustrated in FIG. 2. Accordingly, a frequency detection period controlled by the edge counter 102 must be set such that at least a maximum run-length mark is detected therein. Thus, there is a drawback in reducing a frequency error detection period when using the frequency detector of FIG. 1, thereby preventing a frequency error from being detected at high speed.

Also, a maximum run-length may be affected by noise or inter-symbol interference (ISI). Thus, the performance of the frequency detector of FIG. 1 may degrade in an environment where a signal-to-noise ratio (SNR) is low and/or inter-symbol interference (ISI) is high. Accordingly, when using a PLL circuit with the frequency detector of FIG. 1 in an apparatus such as a high-density optical disc reproducing system in which the SNR is low and the ISI is high, the performance of the frequency detector should not be good.

### SUMMARY OF THE INVENTION

Aspects of the present invention provide a frequency detector and method for detecting a frequency error in a PLL circuit at high speed.

Aspects of the present invention provide a frequency detector in a PLL circuit and a frequency error detecting method, which are capable of precisely detecting a frequency error even under an environment in which a signal-to-noise ratio (SNR) is low and inter-symbol interference (ISI) is high.

According to an aspect of the present invention, a frequency detector of an optical disc reproducing system, the includes a run-length signal detecting unit which detects a run-length signal from a sampled radio-frequency signal in a frequency detection period, based on a predetermined distribution density of the run-length signal; a counter unit including at least one counter which counts the detected run-length signals in the frequency detection period; an edge counter which controls the frequency detection period by counting passing edges of the sampled radio-frequency signal; and a frequency error generating unit which generates a frequency error in the frequency detection period, using the counting result output from the at least one counter and a predetermined reference value.

According to another aspect of the present invention, there is provided a frequency detector of an optical disc reproducing system, includes a run-length signal detecting unit which divides a run-length region into at least two run-length regions based on a predicted distribution density of a run-length signal, and detects a run-length signal from a sampled radio-frequency signal by each run-length region in a frequency detection period; a counter unit including a plurality of counters to count the detected run-length signals for each run-length region in the frequency detection period; an edge counter which counts passing edges of the sampled radio-frequency signal and controls the frequency detection period according to the counting result; and a frequency error generating unit which generates a frequency error in the frequency detection period, using a counter value of each of the plurality of the counters and a predetermined reference value of each run-length region.

According to yet another aspect of the present invention, a frequency detector used in an optical disc reproducing system, includes a run-length signal detecting unit which detects a high-frequency run-length signal from a sampled radio-frequency signal, based on a predicted distribution density of a run-length signal; a counter which counts run-length signals detected by the run-length signal detecting unit in a frequency detection period; an edge counter counts passing edges of the sampled radio-frequency signal and controls the frequency detection period according to the counting result; and a frequency error generating unit which generates a frequency error in the frequency detection period using a counter value output from the counter and a predetermined predicted value.

According to still another aspect of the present invention, a method of detecting a frequency error in an optical disc reproducing system, includes dividing a run-length region, in which a run-length signal is to be detected, into at least two run-length regions based on a predicted distribution density of a run-length signal; detecting a run-length signal from a sampled radio-frequency signal by each run-length region; counting the run-length signals detected in each run-length region; and selecting and outputting a frequency error in the frequency detection period from a plurality of predetermined frequency errors, based on a comparison of a number of run-length signals counted in each run-length region and a predetermined threshold of each run-length region.

According to still another aspect of the present invention, a method of detecting a frequency error in an optical disc reproducing system, includes detecting a high-frequency run-length signal from a sampled radio-frequency signal, based on a predicted distribution density of a run-length signal; counting run-length signals detected in a frequency detection period; and generating a frequency error in the frequency detection period, using the counting result and a predicted value of the high-frequency run-length signal.

Additional aspects and/or advantages of the invention will be set forth in part in the description which follows and, in part, will be obvious from the description, or may be learned by practice of the invention.

### BRIEF DESCRIPTION OF THE DRAWINGS

The above and/or other aspects and advantages of the present invention will become more apparent and more readily appreciated by describing in detail exemplary embodiments thereof with reference to the accompanying drawings in which:

FIG. 1 is a block diagram of a conventional frequency detector;

FIG. 2 is a block diagram of a series of blocks;

FIG. 3 is a block diagram of a frequency detector according to an embodiment of the present invention;

FIG. 4 is a graph illustrating a run-length distribution density estimated according to channel coding characteristics of an optical disc reproducing system, according to an embodiment of the present invention;

FIG. 5 is a graph illustrating a run-length distribution density versus a run-length region divided by a run-length region boundary value, according to an embodiment of the present invention;

FIG. 6 is a detailed block diagram of a run-length signal detecting unit of FIG. 3 according to an embodiment of the present invention;

FIG. 7 is a graph illustrating a run-length distribution density versus a run-length region divided by a predetermined boundary value when the frequency of a sampling clock of an optical disc reproducing system, which is output from a PLL circuit, is less than a target frequency, according to an embodiment of the present invention;

FIG. 8 is a graph illustrating the relationship between an actual number of run-length signals, a predicted number thereof, and a threshold based on the predicted number in each run-length region in the run-length distribution density of FIG. 7, according to an embodiment of the present invention;

FIG. 9 is a graph illustrating a run-length distribution density versus a run-length region divided by a predetermined boundary value when the frequency of a sampling clock of an optical disc reproducing system, which is output from a PLL circuit, is greater than a target frequency, according to an embodiment of the present invention;

FIG. 10 is a graph illustrating the relationship between an actual number of run-length signals, a predicted number thereof, and a threshold based on the predicted number in each run-length region in the run-length distribution density of FIG. 9, according to an embodiment of the present invention;

FIG. 11 is a detailed block diagram of a frequency-error generating unit of FIG. 3 according to an embodiment of the present invention;

FIG. 12 is a block diagram of a frequency detector according to another embodiment of the present invention;

FIG. 13 is a detailed block diagram of a run-length signal detecting unit of FIG. 12 according to an embodiment of the present invention;

FIG. 14 is a detailed block diagram of a frequency-error generating unit of FIG. 12 according to an embodiment of the present invention;

FIG. 15 is a flowchart illustrating a method of detecting a frequency error according to another embodiment of the present invention;

FIG. 16 is a flowchart illustrating a method of detecting a frequency error according to yet another embodiment of the present invention; and

FIG. 17 is a block diagram of a recording and/or reproducing apparatus according to an embodiment of the present invention.

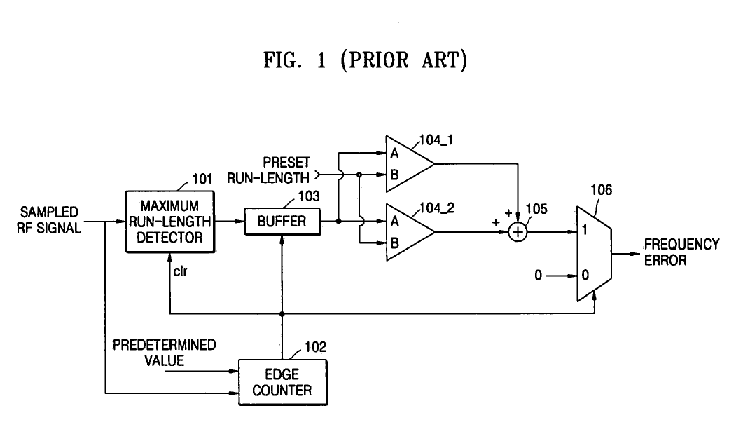

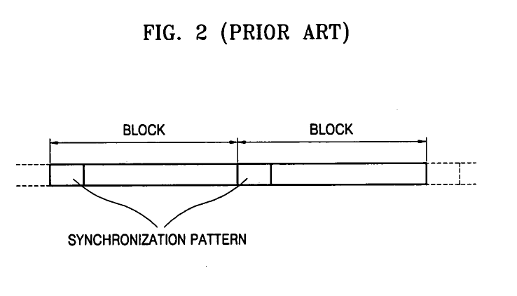

### DETAILED DESCRIPTION OF THE EMBODIMENTS

Hereinafter, exemplary embodiments of the present invention will be described in detail with reference to the accompanying drawings, wherein like reference numerals refer to the like elements throughout. The embodiments are described below in order to explain the present invention by referring to the figures.

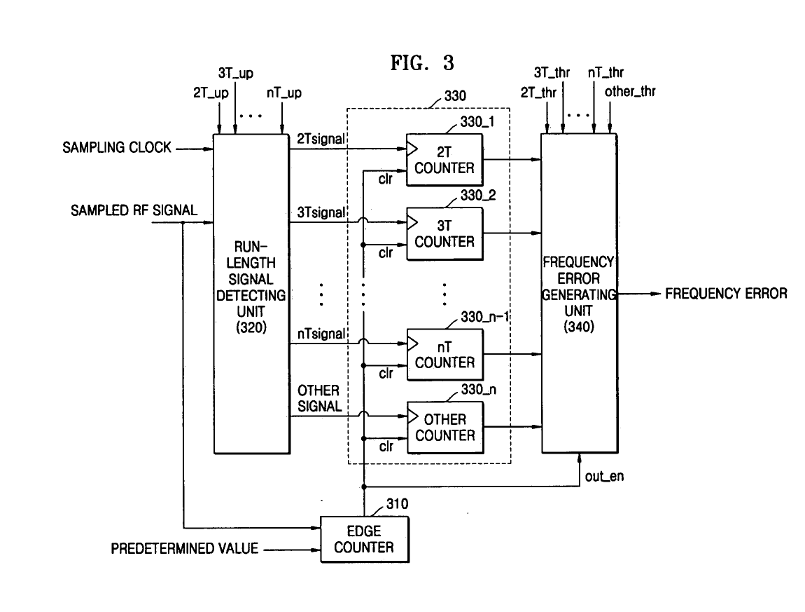

FIG. 3 is a block diagram of a frequency detector according to an embodiment of the present invention. Referring to FIG. 3, the frequency detector includes an edge counter 310, a run-length signal detecting unit 320, a counter unit 330, and a frequency-error generating unit 340. While not required in all aspects, a sampled radio-frequency (RF) signal is received from an analog-to-digital converter (ADC) (not shown) installed in a PLL circuit (not shown) with the frequency detector of FIG. 3. Alternately, the RF signal can be received from a signal processing circuit, (such as a DC component remover) which is connected to an output terminal of the ADC. The ADC samples an input RF signal and outputs the sampled RF signal.

Upon receiving the sampled RF signal, the edge counter 310 counts passing edges of the sampled RF signal to control a frequency detection period. The passing edges include rising edges and falling edges of the sampled RF signal. When the counting result reaches a predetermined value, the edge counter 310 outputs a signal having a positive pulse to control the frequency detection period. Also, after outputting the signal with the positive pulse, the edge counter 310 clears the counting result and counts passing edges of a subsequently sampled RF signal to control a subsequent frequency detection period. When the counting result does not reach the predetermined value, the edge counter 310 outputs “0”. The signal with the positive pulse is transmitted to the counter unit 330 and the frequency-error generating unit 340.

If the predetermined value is a large value, the accuracy of the counting result is increased but a speed of detecting a frequency error is reduced. In contrast, if the predetermined value is a small value, the accuracy of the counting result is low but the speed of detecting a frequency error is increased. Accordingly, while not required in all aspects, the predetermined value is determined based on a range that allows evaluation of the distribution density of a run-length signal versus the sample RF signal.

The run-length signal detecting unit 320 detects run-length signals from the RF signal that is sampled based on the distribution density of the run-length estimated according to channel coding characteristics of the optical disc reproducing system. Specifically, the run-length signal detecting unit 320 partitions the sampled RF signal into at least two run-length regions. The partition is based on the estimated run-length distribution density. The run-length signal detecting unit 320 then classifies and detects run-length signals of the RF signals sampled in the frequency detection period according to the corresponding run-length regions.

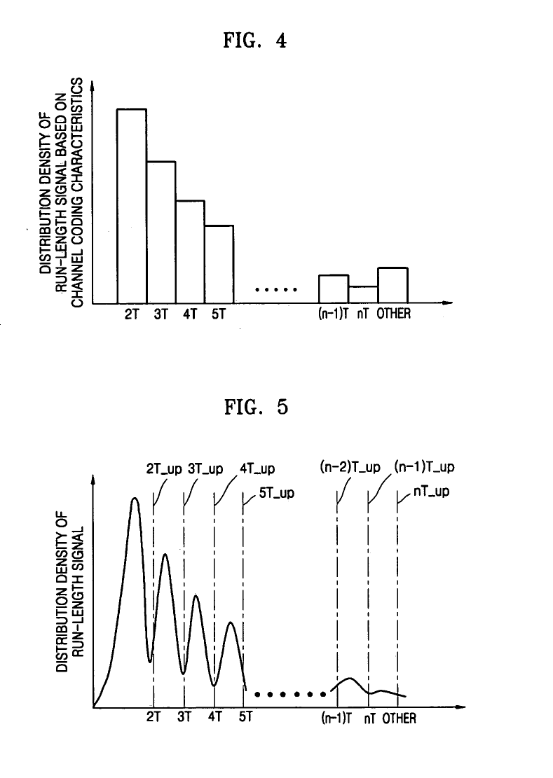

In the shown embodiment, the run-length signal detecting unit 320 divides the run-length region by 1T into n−1 run-length regions from a 2T run-length region to an nT run-length, and other run-length regions including run-lengths except 2T through nT run-lengths. In other words, assuming the distribution density of the run-length estimated according to the channel coding characteristics of the optical disc reproducing system as illustrated in FIG. 4, the run-length signal detecting unit 320 divides the run-length region into n run-length regions, using a predetermined run-length region boundary value 2T_up, 3T_up, . . . , nT_up, as illustrated in FIG. 5.

Here, n may be determined based on a maximum run-length of the various types of optical discs available in the optical disc reproducing system. For instance, when a compact disc (CD), a digital versatile disc (DVD), a blue-ray disc (BD), and a high-definition (HD)-DVD are available in the optical disc reproducing system, a maximum run-length of the CD is 11T, a maximum run-length of the DVD is 11T, a maximum run-length of the BD is 8T, and a maximum run-length of the HD-DVD is 11T. Therefore, n may be set to 11. Further, if compatibility is not needed with plural media, n can be set for only that media.

According to another embodiment, the run-length signal detecting unit 320 divides the run-length region into a run-length region corresponding to a minimum run-length (e.g., 2T) and a run-length region that covers all the other run-lengths except the minimum run-length, and detects the run-length signal from the sampled RF signal. According to another embodiment, the run-length signal detecting unit 320 divides the run-length region into a run-length region corresponding to a run-length in which a run-length signal is most frequently detected, and a run-length region that covers the other run-lengths except the most frequently detected run-length signal, and detects a run-length signal from the sampled RF signal. Although FIGS. 4 and 5 illustrate that the minimum run-length 2T is a most frequently detected run-length, a run-length, other than the minimum run-length 2T may be the most frequently detected run-length according to other embodiments.

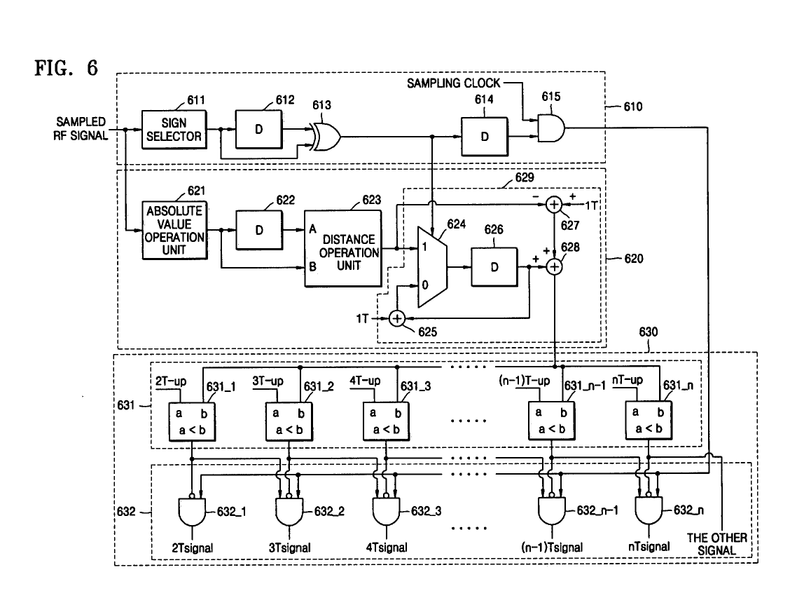

An example of the run-length signal detecting unit 320 is constructed as illustrated in FIG. 6. Referring to FIG. 6, the run-length signal detecting unit 320 includes a zero-crossing point detecting unit 610, a run-length signal detecting unit 620, and an enable signal generating unit 630. The zero-crossing point detecting unit 610 detects a zero crossing point of a sampled RF signal. As shown, the zero-crossing point detecting unit 610 includes a sign selector 611, a first delayer 612, an XOR gate 613, a second delayer 614, and an OR gate 615. The sign selector 611 transforms the sample RF signal into a rectangular shaped signal. That is, the sign selector 611 outputs “1” when the sampled RF signal is positive, and outputs “0” when the sampled RF signal is negative. The first delayer 612 delays an output of the sign selector 611 by a sampling clock. The XOR gate 613 performs an exclusive or operation on outputs of the sign selector 611 and the first delayer 612, and outputs “1” when the sampled RF signal has a zero crossing point. The second delayer 614 delays an output of the XOR gate 613 by the sampling clock. The OR gate 615 performs an OR operation on the sampling clock of the optical disc reproducing system, which is output from the PLL circuit, and an output of the second delayer 614. The OR gate 615 outputs a signal with a rising edge when the sampled RF signal has a zero crossing point.

The run-length signal detecting unit 620 detects a run-length signal from the sampled RF signal. Referring to FIG. 6, the run-length signal detecting unit 620 includes an absolute value operation unit 621, a third delayer 622, a distance operation unit 623, a multiplexer 624, a first adder 625, a fourth delayer 626, a subtracter 627, and a second adder 628. The absolute value operation unit 621 computes an absolute value of the sampled RF signal. The third delayer 622 delays an output of the absolute value operation unit 621 by the sampling clock. The distance operation unit 623 computes a distance d between sampled points, using the output of the absolute value operation unit 621 and an output of the third delayer 622. That is, assuming that the one-sampling clock delayed absolute value output from the third delayer 622 is A and the non-delayed absolute value output from the absolute value operation unit 621 is B, the distance operation unit 623 computes the distance d using the following equation:

$$d = [ \frac{B}{A + B} \times T ] , \qquad ( 1 )$$

where T is a fixed integer that denotes a period of the sampling clock.

The multiplexer 624 transmits an output of the distance operation unit 623 at the zero crossing point, under control by the output of the XOR gate 613. At a point, not the zero crossing point, the multiplexer 624 transmits a signal received from the first adder 625. The fourth delayer 626 delays an output of the multiplexer 624 by the sampling clock. The first adder 625 adds 1T to the output of the multiplexer 624 and transmits the addition result to the multiplexer 624 at the point, other than the zero crossing point.

The subtracter 627 subtracts the output of the distance operation unit 623 from 1T. The second adder 628 adds an output of the subtracter 627 to an output of the fourth delayer 626. The addition result corresponds to the run-length signal detected from the sampled RF signal. The multiplexer 624, the first adder 625, the fourth delayer 626, the subtracter 627, and the second adder 628 may be defined as a logic circuit 629 that detects the run-length signal by summing up 1T between zero crossing points using the outputs of the XOR gate 613 and the distance operation unit 623.

Referring to FIG. 6, the enable signal generating unit 630 generates an enable signal for a run-length region corresponding to the detected run-length signal, using a signal output from the zero-crossing point detecting unit 610, a signal output from the run-length signal detecting unit 620, and the predetermined run-length region boundary value 2T_up, 3T_up, . . . , nT_up. To generate the enable signal, as illustrated in FIG. 6, the enable signal generating unit 630 includes a comparison array 631 and an AND gate array 632. However, other arrays can be used according to other aspects of the invention and according to other run-length region definitions.

The comparison array 631 compares the signal output from the run-length signal detecting unit 620 with the predetermined run-length region boundary value 2T_up, 3T_up, . . . , nT_up using a plurality of comparators 631_1 through 631_n. The comparison array 631 primarily checks the run-length region corresponding to the detected run-length signal according to the comparison result. For instance, if the run-length signal detected by the run-length signal detecting unit 620 is generated between 2T and 3T, the logic level of a signal output from the comparator 631_1 is different from those of signals output from the other comparators 631_2 through 631_n. If the run-length signal detected by the run-length signal detecting unit 620 is generated between 3T and 4T, the logic levels of the signals output from the comparators 631_1 and 631_2 are different from those of the signals output from the other comparators 631_3 through 631_n.

The AND gate array 632 generates an enable signal for the run-length region corresponding to the run-length signal detected by the run-length signal detecting unit 620. Specifically, the AND gate array 632 generates the enable signal by performing an AND operation on a signal output from a corresponding comparator of the comparison array 631, the signal output from the zero-crossing point detecting unit 610, and a signal output from a comparator adjacent to the corresponding comparator, using a plurality of AND gates 632_1 through 632_n. For instance, when the run-length signal detected by the run-length signal detecting unit 620 is generated between 2T and 3T, the signal output from the comparator 631_1 is at a logic high level and the signal output from the comparator 631_2 is at a logic low level. In this case, when the OR gate 615 of the zero-crossing point detecting unit 610 outputs a signal with a rising edge, only a 3T signal output via the AND gate 632_2 of the AND gate array 632 has a positive pulse.

As another example, when the run-length signal detected by the run-length signal detecting unit 620 is generated between 3T and 4T, the signals output from the comparators 631_1 and 631₁₃ 2 are at a logic high level and the signal output from the comparator 631_3 is at a logic low level. In this case, when the OR gate 615 of the zero-crossing point detecting unit 610 outputs a signal with a rising edge, only a 4T signal output via the AND gate 632_3 of the AND gate array 632 has a positive pulse.

In this case, unlike the AND gates 632_2 through 632_n, the AND gate 632_1 corresponding to a 2T signal does not consider the output of the comparator adjacent to the corresponding comparator. A run-length region boundary value set in the comparator adjacent to the corresponding comparator is smaller than that set in the corresponding comparator. For instance, in the case of the AND gate 632_2, the corresponding comparator is the comparator 631_2 and the adjacent comparator is the comparator 631_1.

Enable signals output from the enable signal generating unit 630 are transmitted to the counter unit 330. The counter unit 330 includes at least a counter that counts the run-length signal detected by the run-length signal detecting unit 320 during a frequency detection period. Referring to FIG. 3, the counter unit 330 includes n counters 330_1 through 330_n, since the run-length signal detecting unit 320 uses n run-length regions. Accordingly, a total number of counters to be installed in the counter unit 330 is determined by a total number of run-length regions available in the run-length signal detecting unit 320.

Referring to FIG. 3, run-length regions available in the run-length signal detecting unit 320 include n−1 run-length regions, from a 2T run-length region to an nT run-length region, which are divided into 1 T units, except the 2T to nT run-lengths. Therefore, the n counters 330_1 through 330_n include a 2T counter 330_1 corresponding to a 2T run-length, a 3T counter 330_2 corresponding to a 3T run-length, . . . , an nT counter 330_n−1 corresponding to an nT run-length, and the other counter 330_n corresponding to a run-length except the 2T to nT run-lengths.

The 2T counter 330_1 counts up whenever the run-length signal detecting unit 320 outputs a 2T signal having a positive pulse. The 3T counter 330_2 counts up whenever the run-length signal detecting unit 320 outputs a 3T signal having a positive pulse. The nT counter 330_n−1 counts up whenever the run-length signal detecting unit 320 outputs an nT signal having a positive pulse. The other counter 330_n counts up whenever the run-length signal detecting unit 320 outputs the other signal having a positive pulse.

When the edge counter 310 outputs a signal having a positive pulse to the counter unit 330, count values of the 2T through the other counters 330_1 through 330_n are cleared. The count value of the 2T counter 330_1 indicates the number of 2T run-length signals generated during the frequency detection period. The count value of the 3T counter 330_2 indicates the number of 3T run-length signals generated during the frequency detection period. The count value of the nT counter 330_−n-1 indicates the number of nT run-length signals generated during the frequency detection period. The count value of the other counter 330_n indicates the number of other run-length signals generated during the frequency detection period.

When the run-length signal detecting unit 320 uses two run-length regions, the counter unit 330 may include two counters, each corresponding to each of the two run-length regions, and operate as described above.

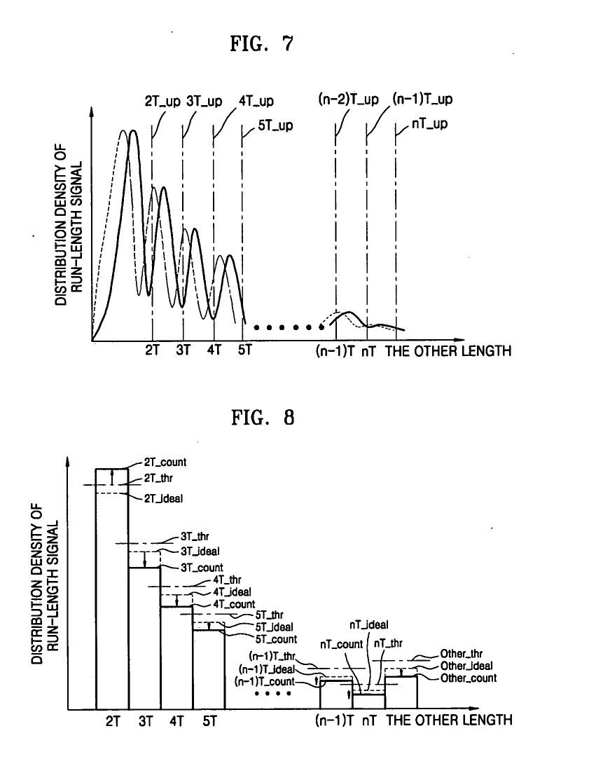

The frequency-error generating unit 340 generates a frequency error in the frequency detection period, using the count values of the n counters 330_1 through 330_n of the counter unit 330 and predetermined reference values 2T_thr through other_thr. Each of the predetermined reference values 2T_thr through other_thr is a threshold that is determined based on an estimated distribution density of a run-length signal that can be generated in a corresponding run-length region in the frequency detection period. That is, when the frequency of a sampling clock of an optical disc reproducing system, which is output from the PLL circuit, is lower than a target frequency, a graph shown in FIG. 5 (which illustrates the distribution density of a run-length signal in each of run-length regions, which are divided based on the predetermined run-length region boundary values 2T_up, 3T_up, . . . , nT_up) shifts to the left side of the graph as indicated by a dotted line in FIG. 7. Thus, as illustrated in FIG. 8, except for a number 2T_count of run-length signals generated in the 2T run-length region, numbers (or run-length distribution densities) 3T_count through nT_count and other_count of the other run-length signals generated in the other run-length regions may be less than predicted numbers (or predicted run-length distribution densities) 3T ideal through nT_ideal and other_ideal of the other run-length signals.

For this reason, a frequency error is detected using the thresholds 2T_thr through other_thr, which are slightly larger than the predicted numbers (or predicted run-length distribution densities) 2T ideal through nT_ideal and other_ideal. FIG. 8 is a graph illustrating the relationship between an actual number nT_count of run-length signals generated in each run-length region, a predicted number nT_ideal of the run-length signals, and a threshold nT_thr determined based on the predetermined number nT_ideal, when the distribution density of the run-length signal changes as illustrated in FIG. 7.

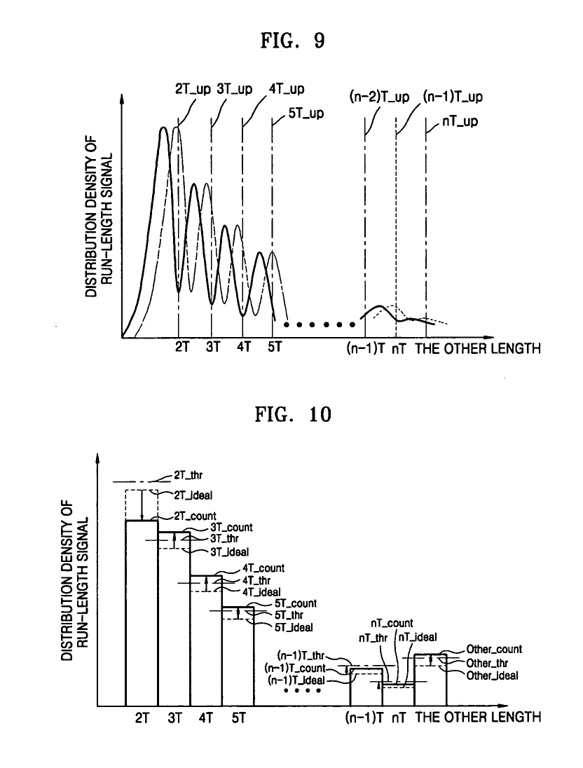

On the other hand, when the frequency of the sampling clock, output from the PLL circuit, for an optical disc reproducing system is higher than the target frequency, the graph shown in FIG. 5 shifts to the right side of the graph, as indicated by dotted lines in FIG. 9. FIG. 10 is a graph illustrating the relationship between an actual number nT_count of run-length signals generated in each run-length region, a predicted number nT_ideal of the run-length signals, and a threshold nT_thr determined based on the predetermined number nT_ideal, when the distribution density of the run-length signal in each run-length region changes as illustrated in FIG. 9. As illustrated in FIG. 10, the actual number nT_count may be less than the predicted number nT_ideal in a run-length region corresponding to a short run-length, e.g., 2T, and the actual number nT_count may be greater than the threshold nT_thr that is determined based on the predicted number nT_ideal in a run-length region corresponding to a run-length greater than 2T.

The predetermined reference value may be determined, based on the threshold that is described with reference to FIGS. 7 through 10 and the actual number of run-length signals generated.

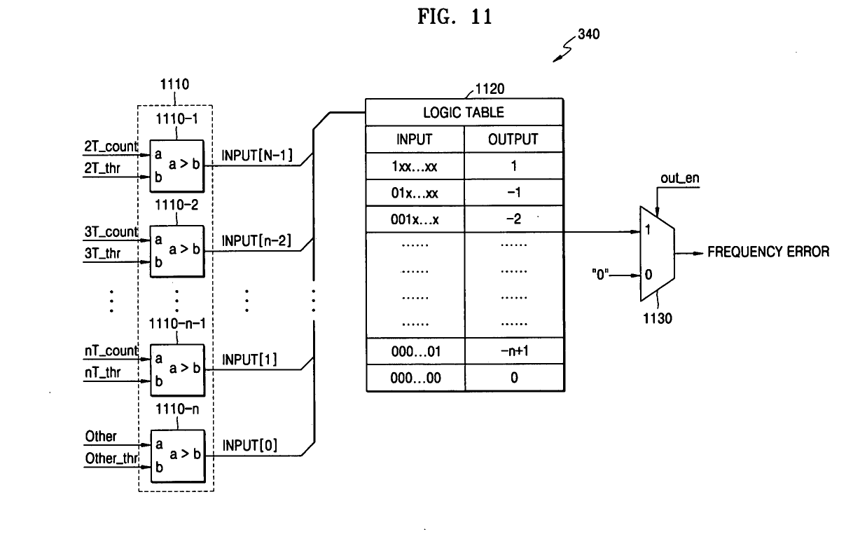

FIG. 11 is a detailed diagram of the frequency-error generating unit 340 according to an embodiment of the present invention. Referring to FIG. 11, the frequency-error generating unit 340 includes a comparison array 1110, a logic table 1120, and a multiplexer 1130. The comparison array 1110 includes a plurality of comparators 1110_1 through 1110_n that correspond to the plurality of the counters 330_1 through 330_n of the counter unit 330, respectively. The comparators 1110_1 through 1110_n compare a counter value of each of the counters 330_1 through 330_n with the predetermined reference value 2T_thr, . . . , other_thr of a corresponding run-length region. The comparators 1110_1 through 1110_n output signals input [n−1] through input [0], which are indicative of the comparison results, to the logic table 1120.

The logic table 1120 selects and outputs one of a plurality of predetermined frequency errors, in response to the signals input [n−1] through input [0]. As illustrated in FIG. 11, the logic table 1120 has a structure by connecting each combination of bits that can be generated according to the comparison results output from the comparison array 1110 and a frequency error corresponding to each combination of bits. A frequency error output from the logic table 1120 is transmitted to the multiplexer 1130. It is understood that the logic table 1120 can store these combinations in a memory of the logic table 1120 or can recall the logic table 1120 from another memory included in a recording and/or reproducing apparatus.

When an output enable signal out_en for controlling the frequency detection period from the edge counter 310 is provided, the multiplexer 1130 transmits a signal output from the logic table 1120 as a frequency error. As described above with respect to the edge counter 310, the output enable signal out en is applied as a positive-pulse signal. When the output enable signal out_en is not provided, the multiplexer 1130 transmits “0”.

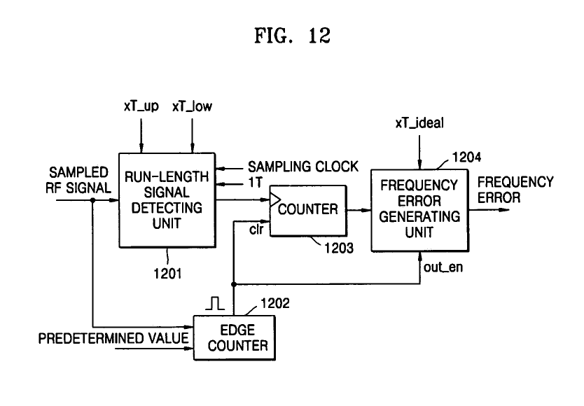

FIG. 12 is a block diagram of a frequency detector according to another embodiment of the present invention. Referring to FIG. 12, the frequency detector includes a run-length signal detecting unit 1201, an edge counter 1202, a counter 1203, and a frequency error generating unit 1204. The run-length signal detecting unit 1201 detects a high-frequency run-length signal from a sampled RF signal, based on the predicted distribution density of the run-length signal according to the channel coding characteristics of an optical disc reproducing system, which is described with reference to FIG. 3.

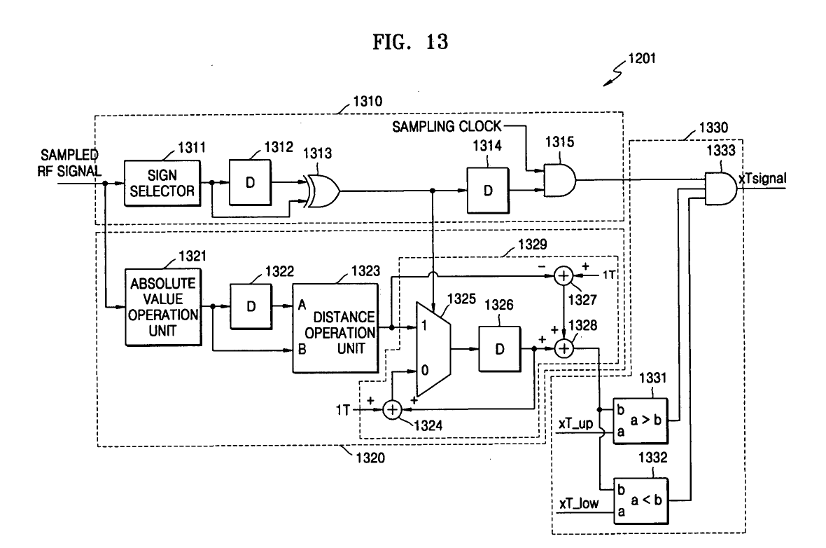

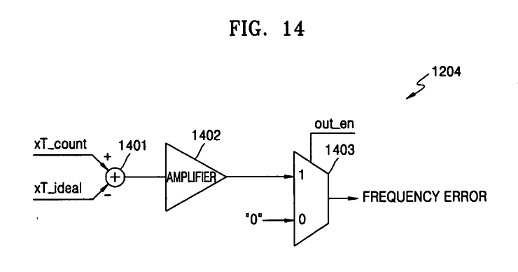

The run-length signal detecting unit 1201 is constructed as illustrated in FIG. 13. FIG. 13 is a detailed block diagram of the run-length signal detecting unit 1201 according to an embodiment of the present invention. Referring to FIG. 13, the run-length signal detecting unit 1201 includes a zero crossing point detecting unit 1310, a run-length signal detecting unit 1320, and an enable signal generating unit 1330. The zero crossing point detecting unit 1310 detects a zero crossing point of the sampled RF signal. The zero crossing point detecting unit 1310 includes a sign selector 1311, a first delayer 1312, an XOR gate 1313, a second delayer 1314, and an AND gate 1315. The construction of the zero crossing point detecting unit 1310 is similar to that of the zero-crossing point detecting unit 610 of FIG. 6 in the shown embodiment.

The run-length signal detecting unit 1320 detects the run-length signal from the sampled RF signal. The run-length signal detecting unit 1320 includes an absolute value operation unit 1321, a delayer 1322, a distance operation unit 1323, and a logic circuit 1329. The construction of the run-length signal detecting unit 1320 is similar to that of the run-length signal detecting unit 620 of FIG. 6 in the shown embodiment.

The enable signal generating unit 1330 generates an enable signal based on whether the high-frequency run-length signal is detected, using the result of comparing a least upper bound xT_up and a greatest lower bound xT_low determined based on the high frequency run-length signal with the run-length signal detected by the run-length signal detecting unit 1320, and the signal output from the zero crossing point detecting unit 1310. Therefore, as illustrated in FIG. 13, the enable signal generating unit 1330 includes a first comparator 1331 that compares the least upper bound xT_up with an output of the run-length signal detecting unit 1320; a second comparator 1332 that compares the greatest lower bound xT_low with the output of the run-length signal detecting unit 1320; and an AND gate 1333 that performs an AND operation on outputs of the zero crossing point detecting unit 1310 and the first and second comparators 1331 and 1332 and outputs an enable signal xTsignal as the operation result.

For instance, if a run-length in which the run-length signal is generated most frequently, is 2T, the least upper bound xT_up and the greatest lower bound xT_low may be set to 2.5T and 0, respectively. If the run-length in which the run-length signal is generated most frequently is greater than 2T, the least upper bound xT_up may be set to a very large value or an infinite value, and the greatest lower bound xT_low may be set to 2.5T.

The operation of the edge counter 1202 is the same as that of the edge counter 310 of FIG. 3 in the shown embodiment. The counter 1203 counts run-length signals detected by the run-length signal detecting unit 1201 in the frequency detection period, and transmits the counting result to the frequency error generating unit 1204. The counting result of the counter 1203 is cleared by the edge counter 1202. The frequency error generating unit 1204 generates a frequency error in the frequency detection period, using the counting result output from the counter 1203 and a predetermined predicted value.

FIG. 14 is a detailed circuit diagram of the frequency error generating unit 1204 according to an embodiment of the present invention. Referring to FIG. 14, the frequency error generating unit 1204 includes a subtracter 1401, an amplifier 1402, and a multiplexer 1403. The subtracter 1401 subtracts a counter value xT_count, which is output from the counter 1203, from a predetermined predicted value xT_ideal. The counter value xT_count indicates a number of high-frequency run-length signals generated in the frequency detection period. The predetermined predicted value indicates a predicted number xT_ideal (or a predicted distribution density) of run-length signals generated in a run-length region corresponding to a run-length in which a run-length signal is generated most frequently. The predetermined predicted value may be defined as a predetermined reference value that is different from the predetermined reference value described with respect to FIG. 3.

The amplifier 1402 amplifies the subtracting result output from the subtracter 1401 to a predetermined value according to a predetermined gain. When an output enable signal out en for controlling the frequency detection period from the edge counter 1202 is provided, the multiplexer 1403 transmits an output of the amplifier 1402 as a frequency error. The output enable signal out_en may be a positive pulse signal. The multiplexer 1403 outputs “0” when the output enable signal out_en is not provided.

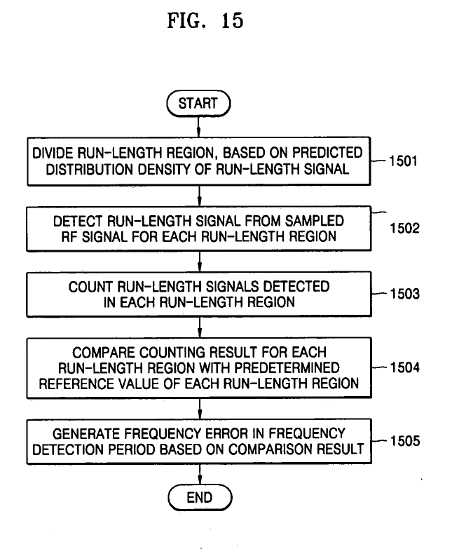

FIG. 15 is a flowchart illustrating a method of detecting a frequency error according to another embodiment of the present invention. Referring to FIGS. 3 and 15, as described above with respect to the run-length signal detecting unit 320 of FIG. 3, a run-length region in which a run-length signal can be detected, is divided into at least two run-length regions, based on the distribution density of the run-length signal which is predicted according to the channel coding characteristics of an optical disc reproducing system (1501). A run-length signal is detected from a sampled RF signal by each run-length region (1502). Run-length signals detected are counted in each run-length region, as described above with reference to the counter unit 330 of FIG. 3 (1503). A frequency error in a frequency detection period is selected and output from a plurality of predetermined frequency errors, based on a comparison of the counting result for each run-length region and a predetermined reference value for each run-length (1504 and 1505). The predetermined reference value is equal to the predetermined reference value used by the frequency-error generating unit 340 of FIG. 3.

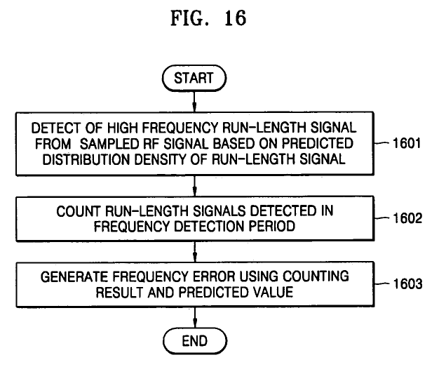

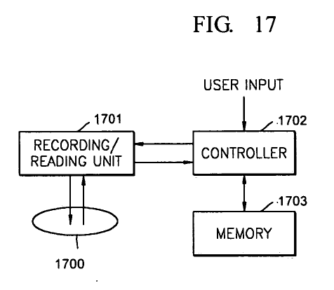

FIG. 16 is a flowchart illustrating a method of detecting a frequency error according to another embodiment of the present invention. Referring to FIGS. 12 and 16, as described above with respect to the run-length signal detecting unit 1201 of FIG. 12, a run-length signal of high frequency is detected from a sampled RF signal, based on the distribution density of a run-length signal predicted according to the channel coding characteristics of an optical disc reproducing system (1601). A number of run-length signals of high frequency detected in the frequency detection period, is counted, as described above with reference to the counter 1203 of FIG. 12 (1602). Afrequency error in the frequency detection period is generated, using the counting result and a predicted value of the run-length signal of high frequency (1603). The frequency error is generated by subtracting the counting result from the predicted value, as described above with respect to the frequency error generating unit 1204 of FIG. 12.

It is understood that the values used by the logic table 1120, the thresholds 2T_thr, . . . , other_thr, and other predetermined numbers can be adjusted and/or updated according to usage of the apparatus and/or through software updates in order to increase the accuracy of the frequency error detection and/or the predicted distribution density.

A program that executes a method of detecting a frequency error according to the present invention can be embodied as computer readable code in at least one computer readable medium. Here, the computer readable medium may be any recording apparatus capable of storing data that is read by a computer system, e.g., read-only memory (ROM), random access memory (RAM), a compact disc (CD)-ROM, a magnetic tape, a floppy disk, an optical data storage device, and so on. Also, the computer readable medium may be a carrier wave that transmits data via the Internet, for example. The computer readable medium can be distributed among computer systems that are interconnected through a network, and the present invention may be stored and implemented as a computer readable code in the distributed system.

As described above, according to the present invention, a frequency error is generated by collecting run-length information from an RF signal sampled based on the distribution density of a run-length signal, which is predicted according to the channel coding characteristics of an optical disc reproducing system. Accordingly, it is possible to more rapidly detect a frequency error than when using a conventional method.

Also, a frequency error is generated by collecting information regarding a run-length in which a run-length signal is detected more frequently, as run-length information regarding the sampled RF signal, based on the predicted distribution density of the run-length signal, thereby realizing a frequency detector that is less sensitive to noise and inter-symbol interference (ISI). Accordingly, it is possible to improve the frequency error detecting performance of a PLL circuit in a system, such as a high-density optical disc reproducing system, which has low noise characteristics and high ISI characteristics.

FIG. 17 is a block diagram of a recording and/or reproducing apparatus according to an embodiment of the present invention. Referring to FIG. 17, the recording apparatus includes a recording/reading unit 1701, a controller 1702, and a memory 1703. The recording/reading unit 1701 records data on a disc 1700, and reads the data from the disc 1700. The controller 1702 records and reproduces disc related data using the PLL circuit according to the present invention as set forth above in relation to FIGS. 3 through 16.

While not required in all aspects, it is understood that the controller 1702 can be computer implementing the method using a computer program encoded on a computer readable medium. The computer can be implemented as a chip having firmware, or can be a general or special purpose computer programmable to perform the method.

In addition, it is understood that, in order to achieve a recording capacity of several dozen gigabytes, the recording/reading unit 1701 could include a low wavelength, high numerical aperture type unit usable to record dozens of gigabytes of data on the disc 1700. Examples of such units include, but are not limited to, those units using light wavelengths of 405 nm and having numerical apertures of 0.85, those units compatible with Blu-ray discs, and/or those units compatible with Advanced Optical Discs (AOD).

While this invention has been particularly shown and described with reference to exemplary embodiments thereof, it will be understood by those skilled in the art that various changes in form and details may be made therein without departing from the spirit and scope of the invention as defined by the appended claims and equivalents thereof.

What is claimed is:

1. A frequency detector in an optical disc reproducing system, comprising:
a run-length signal detecting unit which detects run-length signals from a sampled radio-frequency signal in a frequency detection period, based on a predicted distribution density of run-length signals;
a counter unit including at least one counter which counts the detected run-length signals in the frequency detection period;
an edge counter which counts passing edges of the sampled radio-frequency signal to control the frequency detection period; and
a frequency error generating unit which generates a frequency error in the frequency detection period, using the counting result output from the at least one counter and a predetermined reference value.

2. The frequency detector of claim 1, wherein the run-length signal detecting unit detects the run-length signals from the sampled RF signal according to a corresponding run-length regions into which the run-length signals are divided based on the predicted distribution density.

3. The frequency detector of claim 2, wherein each of the run-length regions corresponds to at least one xT run-length, where x is an integer from 2 to n, and n is determined according to maximum run-lengths of various types of discs compatible with the optical disc reproducing system.

4. The frequency detector of claim 3, wherein the run-length regions further comprise at least one other run-length which covers run-lengths except the 2T to nT run-lengths.

5. The frequency detector of claim 2, wherein the counter unit comprises a total number of the counters equal to a number of run-length regions used by the run-length signal detecting unit.

6. The frequency detector of claim 5, wherein:
each of the counters counts a value corresponds to a number of run-length signals generated in the corresponding run-length region,
the predetermined reference value is a threshold determined based the predicted distribution density of run-length signals to be generated in the corresponding run-length regions in the frequency detection period, and
the frequency error generating unit generates the frequency error, based on a comparison of, for each of the run-length regions, the counter value assigned to the run-length region and the corresponding predetermined reference value.

7. The frequency detector of claim 1, wherein the run-length signal detecting unit detects a run-length signal used for a high frequency from the sampled radio-frequency signal, based on the predicted distribution density of the run-length signal.

8. The frequency detector of claim 7, wherein:
the counter unit comprises a counter,
the predetermined reference value corresponds to the predicted distribution density of the run-length signal used at the high frequency, and
the frequency error generating unit generates the frequency error using a signal corresponding to a value obtained by subtracting the counter value from the predetermined reference value.

9. The frequency detector of claim 6, wherein the edge counter counts the passing edges using a predetermined value which is determined based on a range which allows evaluation of the distribution density of the run-length signals with respect to the sampled RF signal.

10. Afrequency detector in an optical disc reproducing system, comprising:
a run-length signal detecting unit which divides a run-length region into at least two run-length regions based on a predicted distribution density of run-length signals, and detects a run-length signal from a sampled radio-frequency signal by each divided run-length region in a frequency detection period;
a counter unit including a plurality of counters and which counts the detected run-length signals for each divided run-length region in the frequency detection period;
an edge counter which counts passing edges of the sampled radio-frequency signal and controls the frequency detection period according to the counting result; and
a frequency error generating unit which a frequency error in the frequency detection period, using a counter value of each of the plurality of the counters and a predetermined reference value of each run-length region.

11. The frequency detector of claim 10, wherein each of the run-length regions corresponds to at least one xT run-length, where x is an integer from 2 to n and n is determined according to maximum run-lengths of various types of discs available in the optical disc reproducing system.

12. The frequency detector of claim 11, wherein the run-length regions further comprise another run-length which covers run-lengths except the 2T to nT run-lengths.

13. The frequency detector of claim 10, wherein the run-length signal detecting unit comprises:
a zero crossing point detecting unit detecting a zero crossing point of the sampled radio-frequency signal;
a run-length signal detecting unit detecting the run-length signal from the sampled radio-frequency signal; and
an enable signal generating unit which generates an enable signal for the run-length region corresponding to the detected run-length signal using a signal output from the zero crossing point detecting unit, a signal output from the run-length signal detecting unit, and a predetermined run-length region boundary value; and outputs the enable signal to the counter unit corresponding to the run-length region of the detected run-length signal.

14. The frequency detector of claim 13, wherein the zero crossing point detecting unit comprises:
a sign selector which transforms the sampled radio-frequency signal into a rectangular shaped signal;
a first delayer which delays an output of the sign selector;
an XOR gate performing an XOR operation on the output of the sign selector and an output of the first delayer;
a second delayer which delays an output of the XOR gate; and
an AND gate performing an AND operation on a sampling clock of the optical disc reproducing system and an output of the second delayer.

15. The frequency detector of claim 14, wherein the run-length signal detecting unit comprises:
an absolute value operation unit which computes an absolute value of the sampled radio-frequency signal;
a third delayer which delays an output of the absolute value operation unit;
a distance operation unit which computes a distance between the sampled radio-frequency signals, using the output of the absolute value operation unit and an output of the third delayer; and
a logic circuit which accumulates 1T between zero crossing points and detects the run-length signal, using the output of the XOR gate and an output of the distance operation unit, where 1T denotes a period of a sampling clock of the optical disc reproducing system.

16. The frequency detector of claim 15, wherein the logic circuit comprises:
a multiplexer which transmits the output of the distance operation unit at the zero crossing point using the output of the XOR gate;
a fourth delayer which delays an output of the multiplexer;
a first adder which outputs a sum of 1T and an output of the fourth delayer to the multiplexer so that a sum is transmitted via the multiplexer at a point other than the zero crossing point;
a subtracter which subtracts the output of the distance operation unit from 1T; and
a second adder which adds an output of the subtracter and the output of the fourth delayer and outputs the addition result as the detected run-length signal.

17. The frequency detector of claim 13, wherein the enable signal generating unit comprises:
a comparison array which compares the signal output from the run-length signal detecting unit and the predetermined run-length region boundary value using a plurality of comparators, and checks the run-length region corresponding to the detected run-length signal; and
an AND gate array which performs an AND operation on a signal output from a corresponding comparator in the comparison array, the signal output from the zero crossing point detecting unit, and a signal output from a comparator adjacent to the corresponding comparator, using a plurality of AND gates; re-checks the run-length region corresponding to the detected run-length signal; and generates the enable signal according to the checked results.

18. The frequency detector of claim 10, wherein the frequency error generating unit comprises:
a comparison array including a plurality of comparators which respectively correspond to the plurality of the counters and which compares a counter value of each of the counters with the predetermined threshold of the corresponding run-length region;
a logic table which selects and outputs one of a plurality of predetermined frequency errors stored in the table in response to signals output from the comparators of the comparison array; and
a multiplexer which transmits a signal output from the logic table as the frequency error when the edge counter provides an output enable signal for controlling the frequency detection period.

19. Afrequency detector in an optical disc reproducing system, comprising:
a run-length signal detecting unit which detects high-frequency run-length signals from a sampled radio-frequency signal, based on a predicted distribution density of run-length signals;
a counter which counts the high-frequency run-length signals detected by the run-length signal detecting unit in a frequency detection period;
an edge counter which counts passing edges of the sampled radio-frequency signal and controls the frequency detection period according to the counting result; and
a frequency error generating unit which generates a frequency error in the frequency detection period using a counter value output from the counter and a predetermined predicted value.

20. The frequency detector of claim 19, wherein the run-length signal detecting unit comprises:
a zero crossing point detecting unit which detects a zero crossing point of the sampled radio-frequency signal;
a run-length signal detecting unit which detects run-length signals from the sampled radio-frequency signal; and
an enable signal generating unit which generates an enable signal based on whether the high-frequency run-length signal is detected as compared to other run-length signals, using a comparison of a least upper bound and a greatest lower bound determined based on the high-frequency run-length signal with the detected run-length signal, and a signal output from the zero crossing point detecting unit.

21. The frequency detector of claim 19, wherein the frequency error generating unit comprises:
a subtracter which subtracts the counter value, which is output from the counter, from the predetermined predicted value;
an amplifier which amplifies an output of the subtracter to a predetermined value; and
a multiplexer which transmits an output of the amplifier as the frequency error when the edge counter transmits an output enable signal for controlling the frequency detection period.

22. A method of detecting a frequency error in an optical disc reproducing system, comprising:
dividing a run-length region, in which a run-length signal is to be detected, into at least two run-length regions based on a predicted distribution density of run-length signals;
detecting run-length signals from a sampled radio-frequency signal according to the each divided run-length regions;
counting the run-length signals detected in each divided run-length region; and
selecting and outputting a frequency error in the frequency detection period from a plurality of predetermined frequency errors, based on a comparison of a number of run-length signals counted in each divided run-length region and a predetermined threshold of each run-length region.

23. A method of detecting a frequency error in an optical disc reproducing system, comprising:
detecting high-frequency run-length signals from a sampled radio-frequency signal, based on a predicted distribution density of run-length signals including high-frequency and other run-length signals;
counting the high-frequency run-length signals detected in a frequency detection period to produce a counting result; and
generating a frequency error in the frequency detection period, using the counting result and a predicted value of the high-frequency run-length signal.

24. The method of claim 23, wherein the generation of the frequency error comprises generating the frequency error based on a result obtained by subtracting the counting value from the predicted value.

25. The frequency detector of claim 19, wherein the high-frequency run-length signal comprises a high-frequency run-length used in a Blue-ray type optical disc reproducing system.

26. The frequency detector of claim 19, wherein the high-frequency run-length signal comprises a high-frequency run-length used in a high definition digital versatile disc (HD-DVD) type optical disc reproducing system.

27. A frequency detector in an optical disc reproducing system, comprising:
a run-length signal detecting unit which detects lengths of run-length signals of a sampled radio-frequency signal and separates the run-length signals into corresponding run-length regions according to the detected lengths;
a plurality of counter units corresponding to the number of run-length regions to generate a counting result, each counter unit to count the detected run-length signals separated into the corresponding run-length region to provide a region counting result included in the counting result; and
a frequency error generating unit which generates a frequency error using the counting result.

28. The frequency detector of claim 27, wherein:
the run-length regions comprise a first run-length region corresponding to run-length signals having a first length, and a second run-length region corresponding to run-length signals having a second length other than the first length,
the run-length signal detecting unit separates the run-length signals having the first length into the first run-length region and the run-length signals having the second length into the second run-length region according to the detected lengths, and
the plurality of counter units comprises a first counter unit which counts the detected run-length signals separated into the first run-length region to provide a first region counting result included in the counting result, and a second counter unit which counts the detected run-length signals separated into the second run-length region to provide a second region counting result included in the counting result.

29. The frequency detector of claim 27, wherein:
the run-length regions includes first through n run-length regions corresponding to run-length signals having first through n lengths, where n is a maximum run length includable in the radio frequency signal,
the run-length signal detecting unit detects the first through n lengths of the run-length signals and separates the run-length signals into corresponding first and n run-length regions according to the detected lengths, and
the plurality of counter units comprises first through nth counter units to generate the counting result, where the first counter unit counts the detected run-length signals separated into the first run-length region to provide a first region counting result included in the counting result, and the second through nth counter units count the corresponding detected run-length signals separated into the second through nth run-length regions to provide corresponding second through nth region counting results included in the counting result.

30. The frequency detector of claim 29, wherein n corresponds 11T run lengths.

31. The frequency detector of claim 29, wherein n corresponds 8T run lengths.

32. An optical recording and/or reproducing apparatus including the frequency detector of claim 29, wherein n corresponds to the maximum run length of an optical recording medium reproduced by the apparatus.

33. An optical recording and/or reproducing apparatus including the frequency detector of claim 27, wherein the number of run-length regions and the number of counter units correspond to a maximum run length of an optical recording medium reproduced by the apparatus.

34. The frequency detector of claim 27, wherein the frequency error generating unit compares the region counting results for the run-length regions with a preselected profile of expected region counting results to detect a comparison result, and generates the frequency error according to the detected comparison result.

35. The frequency detector of claim 34, wherein the frequency error generating unit includes:
a memory which stores, for each potential comparison result, a frequency error, and
a frequency error unit which detects the comparison, selects from the memory one of the frequency errors corresponding to the comparison result, and outputs the selected frequency error.

36. A method of detecting a frequency error in an optical disc reproducing system, comprising:
detecting run-length signals from a sampled radio-frequency signal;
assigning each of the detected run-length signals one of a plurality of run-length regions having a length corresponding to the detected run-length signals;
counting the run-length signals detected in each run-length region; and
outputting a frequency error based on a comparison of a number of run-length signals counted in each run-length region.
